(19) United States
(12) Patent Application Publication
(10) Pub. No.: US 2014/0154826 A1
(43) Pub. Date: Jun. 5, 2014

(54) ETCH STOP LAYERS IN NITRIDE SEMICONDUCTORS CREATED BY POLARITY INVERSION

(71) Applicant: PALO ALTO RESEARCH CENTER INCORPORATED, (US)

(72) Inventors: Brent S. Krusor, Fremont, CA (US); John E. Northrup, Palo Alto, CA (US)

(73) Assignee: PALO ALTO RESEARCH CENTER INCORPORATED, Palo Alto, CA (US)

(21) Appl. No.: 13/691,413

(22) Filed: Nov. 30, 2012

(51) Int. Cl. H01L 33/00

(52) U.S. Cl. CPC H01L 33/0075
USPC 438/46

(57) ABSTRACT

A method of producing a semiconductor device can include receiving a Group III-N wafer as a substrate, initiating a first inversion domain boundary layer to form a thin etch stop layer, terminating the etch stop layer with a second inversion domain boundary layer, and subsequently continuing the active region growth.

### GOVERNMENT FUNDING

This invention was made with U.S. Government support through the Defense Advanced Research Projects Agency (DARPA) under Army Research Laboratory (ARL) Cooperative Agreement # W911NF-10-02-0102. The Government has certain rights in this invention.

### TECHNICAL FIELD

The disclosed technology relates to semiconductors and, more particularly, to the design and manufacturing of certain semiconductor devices such as light emitting devices (LEDs), for example.

### BACKGROUND

In many light emitting device (LED) designs, it is necessary to extract light from the backside of the device because layers above the active light-emitting layers of the device are usually, at least to some extent, optically-absorbing. In the case of laser diodes, for example, an optically-absorbing substrate generally contributes to waveguide materials loss, thus increasing the amount of gain required to achieve lasing. Aluminum nitride (AlN) substrates are electrically insulating, so leaving such substrates on the device may preclude vertical injection laser diode architectures having backside contacts. In addition, some AlN substrates may contain a high concentration of impurities. These impurities can give rise to a high level of optical absorption. Such absorption can reduce the efficiency of light extraction from the backside of the LED. In such designs, it is usually useful to be able to remove this AlN substrate.

### BRIEF DESCRIPTION OF THE DRAWINGS

FIG. 1 is a schematic figure showing the relation between crystallographic orientation and chemical structure of wurtzite aluminum nitride (AlN) in accordance with certain embodiments of the disclosed technology.

FIG. 2 illustrates an etch stop layer defined by two c-plane inversion domain boundaries in accordance with certain embodiments of the disclosed technology.

FIG. 3 illustrates an example of a first method of producing a semiconductor device, e.g., an LED, in accordance with certain embodiments of the disclosed technology.

FIG. 4 illustrates an example of a second method of producing a semiconductor device, e.g., an LED, in accordance with certain embodiments of the disclosed technology.

### DETAILED DESCRIPTION

Embodiments of the disclosed technology generally include one or more processes in which etch stop layers may be created by inverting the polarity of the crystal and leveraging certain properties of the material, e.g., that etching may occur on only one surface of the material. In certain embodiments, bulk aluminum nitride (AlN) material, which generally has a natural polarity with one surface of the crystal being a nitrogen-terminated face or nitrogen-face (N-face) and the opposing surface being an aluminum-terminated face or aluminum-face (Al-face), may be used as a substrate. In certain alternative embodiments, aluminum gallium nitride (AlGaN) may be used as a substrate.

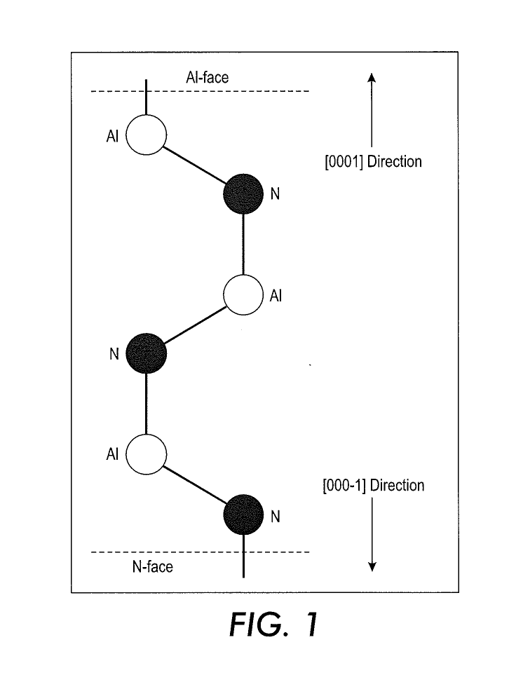

FIG. 1 is a schematic figure showing the relation between crystallographic orientation and chemical structure of wurtzite AlN in accordance with certain embodiments of the disclosed technology. In the example, the N-face and the Al-face are both defined. At the Al-face, the [0001] direction generally points out of the material and into the upward space outside the material. At the N-face, the [000-1] direction generally points out of the material and into the downward space outside the material.

In the example, the nitrogen-terminated face may be readily etched while the aluminum-terminated face is generally not attacked by the etchant. Epitaxial growth of device structures may be initiated on the aluminum-terminated face because growth on this face generally produces better quality crystals. The exposed backside of the substrate, therefore, has the nitrogen-terminated face. The AlN substrate may thus be removed by etching the nitrogen-terminated face.

The polarity of the AlN substrate can usually be reversed during molecular beam epitaxy (MBE) or metalorganic chemical vapor deposition (MOCVD) growth by controlling the relative flux of the Al and N during exposure of the growth surface to magnesium (Mg). This typically results in a Mg-induced reversal of polarity at the interface and thus creates an effective etch stop layer by presenting an Al-face to the etch front as it reaches the inversion layer.

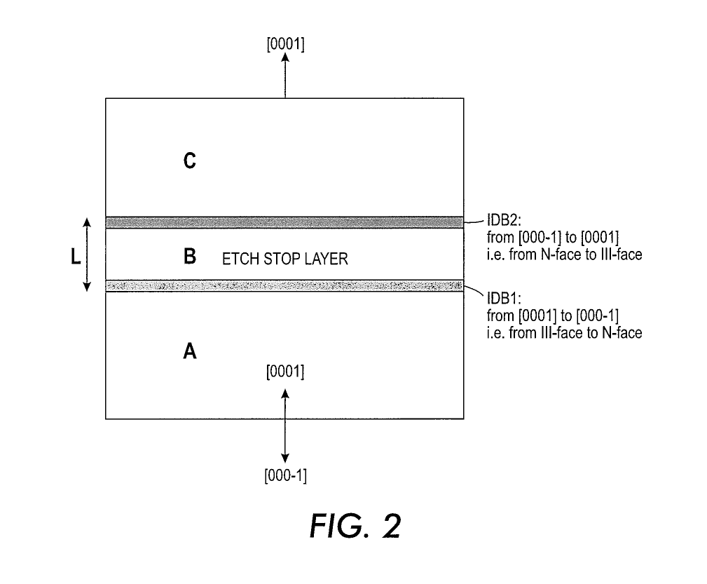

FIG. 2 illustrates an etch stop layer defined by two c-plane inversion domain boundaries (IDBs) in accordance with certain embodiments of the disclosed technology. In the example, Region A can be attacked and removed by the etchant, whereas Region B, the etch stop layer, cannot be etched. In the etch stop layer, the etching rate is so low as to result in a negligible loss of material during the time the etchant is in contact with the surface. Region B may be made thin by placing two Mg-induced IDBs (IDB1 and IDB2) a short distance L apart. The active region may be grown within region C. In general, IDB1 and IDB2 may be structurally inequivalent. For example, IDB1 may invert the polarity so that the growth surface is changed from an Al-face to a N-face, and IDB2 may invert the polarity so that the growth surface is changed from the N-face back to the Al-face.

The etch stop layer, e.g., Region B, may be relatively thin. Subsequent to the initiation of this layer, another layer, e.g., Region C, having the original polarity may be initiated and grown by a similar manipulation of the Mg, Al, and N flows. This layer may then present an Al growth surface for epitaxial growth of the device structure.

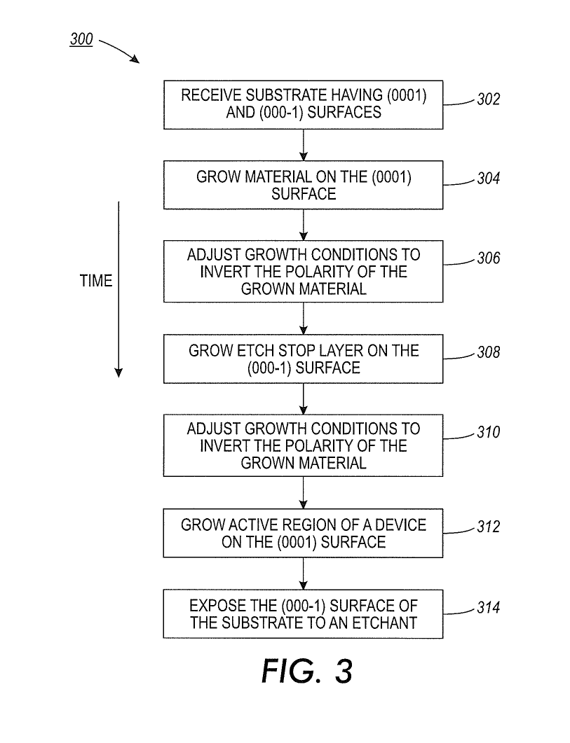

FIG. 3 illustrates a first example of a method 300 of producing a semiconductor device, e.g., an LED, in accordance with certain embodiments of the disclosed technology. At 302, a substrate, e.g., an AlN substrate, AlGaN substrate or other suitable substrate, having (0001) and (000-1) surfaces is received or otherwise provided.

At 304, a layer of material is grown on the substrate by directing a flux of Al atoms, or Al-containing molecules such as tri-methyl-aluminum, and a flux of N atoms, or N-containing molecules such as N₂ or NH₃, onto the (0001) surface of the substrate. In certain situations, where the grown material is AlₓGa₁₋ₓN, a flux of Ga atoms or Ga-containing molecules would generally be present. Here, the growth surface orientation (GSO) is (0001). The material present following completion of the steps at 302 and 304 may constitute region A as shown in FIG. 2.

At 306, the polarity of the grown material is inverted, e.g., by temporarily adding a flux of magnesium or magnesium-containing molecules. The GSO is thus (000-1). For example, the flux of magnesium or magnesium-containing molecules may be selected such that approximately 1.5 monolayers of magnesium is incorporated into the material, which can result in the inversion of the polarity. Alternatively, the inversion of polarity may be accomplished by temporarily adding a flux of oxygen or oxygen-containing molecules, which may be selected such that approximately 1.5 monolayers of oxygen is incorporated into the material.

At 308, a growth is caused to occur on the (000-1) surface. This growth may include a layer of material, e.g., AlGaN, that is sufficiently thick to act as an etch stop layer. The thickness L of such an etch stop layer can be approximately 10 nm, for example.

At 310, the polarity of the grown material is inverted back such that growth may now take place on the (0001) surface. The GSO is thus (0001). The inversion of polarity may be accomplished by temporarily adding a flux of magnesium atoms or magnesium-containing molecules, for example.

At 312, one or more active regions, e.g., layers in which light may be emitted, of a semiconductor device, such as an LED or laser diode device, are grown on the (0001) surface.

At 314, the (000-1) surface of the substrate is exposed to an etchant, which may be used to remove the material in a certain region, e.g., region A in FIG. 2. Alternatively or in addition thereto, the etching may be used to remove at least substantially all of the substrate or all of the substrate and at least substantially all of the material grown at 304. In certain embodiments, the etching may stop automatically after the etchant has removed all of the material up to the beginning of the etch stop layer.

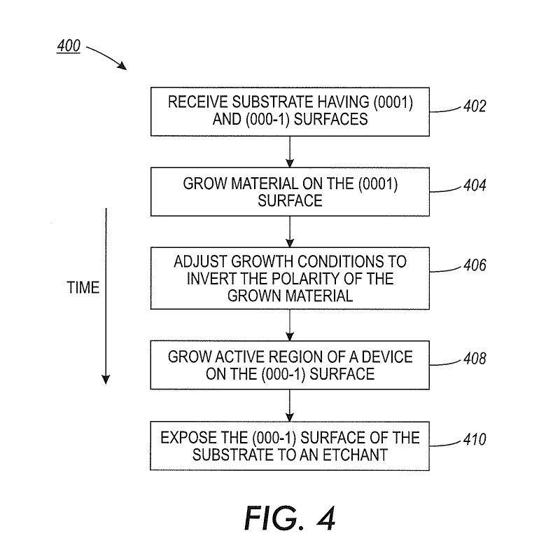

FIG. 4 illustrates a second example of a method 400 of producing a semiconductor device, e.g., an LED, in accordance with certain embodiments of the disclosed technology. At 402, a substrate, e.g., an AlN substrate, AlGaN substrate or other suitable substrate, having (0001) and (000-1) surfaces is received or otherwise provided.

At 404, a layer of material is grown on the substrate by directing a flux of Al atoms, or Al-containing molecules such as tri-methyl-aluminum, and a flux of N atoms, or N-containing molecules such as N₂ or NH₃, onto the (0001) surface of the substrate. In certain situations, where the grown material is AlₓGa₁₋ₓN, a flux of Ga atoms or Ga-containing molecules would generally be present. Here, the growth surface orientation (GSO) is (0001). The material present following completion of the steps at 402 and 404 may constitute region A as shown in FIG. 2.

At 406, the polarity of the grown material is inverted, e.g., by temporarily adding a flux of magnesium or magnesium-containing molecules. The GSO is thus (000-1). For example, the flux of magnesium or magnesium-containing molecules may be selected such that approximately 1.5 monolayers of magnesium is incorporated into the material, which can result in the inversion of the polarity. Alternatively, the inversion of polarity may be accomplished by temporarily adding a flux of oxygen or oxygen-containing molecules, which may be selected such that approximately 1.5 monolayers of oxygen is incorporated into the material.

At 408, one or more active regions, e.g., layers in which light may be emitted, of a semiconductor device, such as an LED or laser diode device, are grown on the (000-1) surface.

At 410, the (000-1) surface of the substrate is exposed to an etchant, which may be used to remove the material in a certain region, e.g., region A in FIG. 2. Alternatively or in addition thereto, the etching may be used to remove at least substantially all of the substrate or all of the substrate and at least substantially all of the material grown at 404. In certain embodiments, the etching may stop automatically after the etchant has removed all of the material up to the beginning of the etch stop layer.

Certain embodiments generally include a growth strategy in which most of a semiconductor device, e.g., an LED, is grown by a first process, such as an MOCVD process, while the etch stop layer is grown by a second process, such as an MBE process. For example, steps 304 and 312 in FIG. 3 may involve growth by an MOCVD process and steps 406-410 in FIG. 4 may involve growth by an MBE process. Alternative embodiments may include using MOCVD growth for all steps or MBE growth for all steps. Certain alternative embodiments may include employing an approach in which only one IDB is employed. In such approaches, one could initially provoke growth on the Al-face, invert the growth to the N-face, grow the device structure on the N-face, and then remove the AlN substrate up to the etch stop layer.

With reference to FIG. 2, it may be advantageous in certain situations for Region C to have the same in-plane lattice constant as the AN or AlₓGa₁₋ₓN substrate. Thus, growth of Region C may include growth of a thick AlN or AlₓGa₁₋ₓN layer so that, after removal of Region A, the wafer is not bowed and the in-plane lattice constant of Region C and the layers situated above are the same as the bulk AlN or AlₓGa₁₋ₓN substrate.

Lateral control of the polarity of the material may be used to laterally define the regions either during growth or subsequent etching of the substrate. This might also be used as an intrinsic back surface texturing technique based on selection of the lateral dimensions. By patterning the initial template, one may initiate N-face growth in certain areas and Al-face growth in other areas. Etching away the N-face regions on the back surface, for example, may give rise to texturing that could improve light extraction efficiency based on selection of the lateral dimensions.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A method of producing a semiconductor device, comprising:
receiving a substrate;
forming a multilayer structure on the substrate, wherein at least one interface between two layers in the multilayer structure comprises a first inversion domain boundary; and
at least substantially removing a first outer layer comprising the substrate and material between the substrate and the inversion domain boundary that is nearest to the substrate.

2. The method of claim 1, in which the semiconductor device is a light emitting device (LED).

3. The method of claim 1, wherein the at least substantially removing comprises performing an etching process on the first outer layer.

4. The method of claim 1, wherein the first inversion domain boundary comprises a c-plane magnesium-induced inversion domain boundary.

5. The method of claim 4, wherein the magnesium-induced inversion domain boundary contains at least substantially 1.5 monolayers of magnesium.

6. The method of claim 4, wherein the magnesium-induced inversion domain boundary contains between substantially 0.5 and 2.5 ML of magnesium.

7. The method of claim 1, wherein the polarity of the semiconductor device is inverted from aluminum-face to nitrogen-face.

8. The method of claim 1, wherein the forming comprises placing a second inversion domain boundary at a second side of an inner layer, the second side being opposite a first side that is nearer to the first inversion domain boundary.

9. The method of claim 8, wherein each of the first and second inversion domain boundaries is magnesium-induced.

10. The method of claim 8, wherein one of the first and second inversion domain boundaries is magnesium-induced, and wherein the other one of the first and second inversion domain boundaries is oxygen-induced.

11. The method of claim 9, wherein the oxygen-induced inversion domain boundary contains at least substantially 1.5 monolayers of oxygen.

12. The method of claim 1, further comprising growing an active region within a second outer layer.

13. The method of claim 12, wherein the active region comprises a transparent aluminum gallium nitride alloy.

14. The method of claim 13, wherein the transparent aluminum gallium nitride is sufficiently thick such that the second outer layer does not bend or bow subsequent to the at least substantial removal of the first outer layer.

15. The method of claim 13, wherein the transparent aluminum gallium nitride is sufficiently thick such that the in-plane lattice constant in the second outer layer remains at least substantially identical to that of the first outer layer subsequent to the at least substantial removal of the first outer layer.

16. The method of claim 1, wherein the first outer layer comprises a nitrogen-terminated face.

17. The method of claim 12, wherein the second outer layer comprises an aluminum-terminated face.

18. The method of claim 17, further comprising growing a device structure on the second outer layer.

19. The method of claim 18, wherein the growing comprises an epitaxial growth process.

20. The method of claim 19, wherein the epitaxial growth process comprises an MOCVD process or an MBE process.
